(19) United States
(12) Patent Application Publication
(10) Pub. No.: US 2026/0331165 A1
(43) Pub. Date: Oct. 22, 2026

(54) MEMORY DEVICE

(71) Applicant: KOREA ADVANCED INSTITUTE OF SCIENCE AND TECHNOLOGY, Daejeon (KR)

(72) Inventors: Seong Hwan Cho, Daejeon (KR); Dong Hwan Kim, Daejeon (KR)

(73) Assignee: KOREA ADVANCED INSTITUTE OF SCIENCE AND TECHNOLOGY, Daejeon (KR)

(21) Appl. No.: 19/104,607

(22) PCT Filed: Jan. 13, 2023
(86) PCT No.: PCT/KR2023/000623

§ 371 Date: Feb. 18, 2025

(30) Foreign Application Priority Data
Aug. 19, 2022 (KR) 10-2022-0104257

(51) Int. Cl. G11C 11/4094; G11C 11/406; G11C 11/4096; G11C 11/4097; H03M 1/12; H03M 1/66

(52) U.S. Cl. CPC G11C 11/4094; G11C 11/406; G11C 11/4096; G11C 11/4097; H03M 1/12; H03M 1/66

(57) ABSTRACT

Disclosed is a memory device including a memory cell storing data by operations of word lines and bit lines. The memory device comprises: switches that form word lines and bit lines in rows and columns and are connected to the word lines and the bit lines; an amplifier that amplifies and outputs an analog voltage recorded on the memory cell; an analog-to-digital converter connected to an output terminal of the amplifier, and a digital-to-analog converter that outputs an input analog voltage obtained by converting, into an analog voltage, recorded digital data or output digital data output by the analog-to-digital converter.

### FIELD OF THE DISCLOSURE

The present disclosure relates to a memory device; and more particularly, the memory device that reduces idle time of circuit elements for reading data from a memory cell and writing data on the memory cell.

### BACKGROUND OF THE DISCLOSURE

DRAM, a well-known memory in semiconductor memory devices, records data in cells each of which is configured as one transistor and one capacitor by recording one bit of information. For example, “0” or “1” is recorded in a cell depending on whether its corresponding capacitor is charged or discharged.

In addition, multi-level DRAM has been recently proposed to increase data storage capacity by storing more than one bit of data in a single cell, unlike the conventional DRAM that stores one bit of information of “0” or “1”, in the single cell configured as the one transistor and the one capacitor.

Further, the DRAM may determine whether to access the capacitor by turning the transistor on/off through a wordline and may write data on the capacitor or read the data written on the capacitor through a bitline.

For example, an operation of the DRAM is described by referring to FIGS. 1A and 1B. From them, it can be seen that by enabling a reference voltage switch connected to a bitline BL, the bitline is pre-charged when the reference voltage VM is supplied to the bitline BL. Further, by enabling the transistor of the memory cell through a wordline WL, an analog voltage recorded on the capacitor of the memory cell is amplified by an amplifier. Furthermore, by enabling an analog-to-digital converter ADC, digital data corresponding to the analog voltage recorded on the capacitor of the memory cell is outputted by the analog-to-digital converter ADC. Moreover, by enabling a digital-to-analog converter DAC, digital data is converted into the analog voltage and then the analog voltage is applied to the memory cell through the bitline BL to thereby record the digital data on the memory cell or refresh the memory cell.

Herein, it can be seen from FIG. 1B that an operation #2 OP #2 is performed after an operation #1 OP #1 is completed, therefore, a read-write cycle becomes long and idle time of each circuit element included in the memory device, i.e., the amplifier AMP, the analog-to-digital converter ADC, and the digital-to-analog converter DAC becomes very long.

Accordingly, the applicant of the present disclosure proposes a memory device that may decrease the idle time of each circuit element thereof.

### DETAILED EXPLANATION OF THE DISCLOSURE

### Objects of the Invention

It is an object of the present disclosure to solve all the aforementioned problems.

It is another object of the present disclosure to improve a data processing capability per unit time of circuit elements included in a memory device.

It is still another object of the present disclosure to reduce an overall circuit area of the memory device.

It is still yet another object of the present disclosure to reduce idle time of the circuit elements included in the memory device.

### Means of Solving the Problem

In order to accomplish objects above and characteristic effects to be described later of the present disclosure, distinctive structures of the present disclosure are described as follows.

In accordance with one aspect of the present disclosure, there is provided a memory device including memory cells operated by wordlines and bitlines to store data therein, including: a (1_1)-st switch having one end connected to a first specific bitline which is one of bitlines included in a first memory cell matrix, wherein first wordlines and first bitlines are configured as rows and columns in the first memory cell matrix, wherein first memory cells operated by signals of the first wordlines are connected to the first bitlines in the first memory cell matrix, wherein first reference voltage switches configured to provide a reference voltage when being enabled in a pre-charge mode are connected to the first bitlines in the first memory cell matrix; a (1_2)-nd switch having one end connected to a second specific bitline which is one of bitlines included in a second memory cell matrix, wherein second wordlines and second bitlines are configured as rows and columns in the second memory cell matrix, wherein second memory cells operated by signals of the second wordlines are connected to the second bitlines in the second memory cell matrix, wherein second reference voltage switches configured to provide the reference voltage when being enabled in the pre-charge mode are connected to the second bitlines in the second memory cell matrix; an amplifier configured to amplify an analog voltage written on a selected one of first specific memory cells connected to the first specific bitline or a selected one of second specific memory cells connected to the second specific bitline, wherein the amplifier has a first input end connected to a reference voltage end that supplies the reference voltage and a second input end connected to an opposite end of the (1_1)-st switch and an opposite end of the (1_2)-nd switch; an analog-to-digital converter connected to an output end of the amplifier, wherein the analog-to-digital converter is configured to convert an output voltage of the amplifier into digital data and thus generate digital output data; a digital-to-analog converter configured to convert (i) digital record data to be written on one of memory cells connected to the first specific bitline or the second specific bitline or (ii) the digital output data outputted from the analog-to-digital converter, into an analog voltage, to thereby output analog input data; a (2_1)-st switch having one end connected to the first specific bitline and an opposite end connected to an output end of the digital-to-analog converter; and a (2_2)-nd switch having one end connected to the second specific bitline and an opposite end connected to an output end of the digital-to-analog converter.

As one example, in an operation mode for writing a (2_1)-st digital record data on a (2_1)-st specific memory cell among the second specific memory cells connected to the second specific bitline after reading a (1_1)-st digital record data written on a (1_1)-st specific memory cell among the first specific memory cells connected to the first specific bitline, (i) the first specific bitline is pre-charged by a (1_1)-st operation mode in which a first specific reference voltage switch connected to the first specific bitline is enabled and the (1_1)-st switch is enabled, (ii) (ii-1) a (1_1)-st analog voltage corresponding to the (1_1)-st digital record data written on the (1_1)-st specific memory cell is amplified through the amplifier to output a (1_1)-st output voltage, and (ii-2) a (2_1)-st input analog voltage converted from the (2_1)-st digital record data to be written on the (2_1)-st specific memory cell through the digital-to-analog converter is applied to the second specific bitline to write the (2_1)-st digital record data on the (2_1)-st specific memory cell, by a (1_2)-nd operation mode in which the first specific reference voltage switch is disabled, the (1_1)-st specific memory cell is enabled, the (2_1)-st specific memory cell is enabled, the (2_2)-nd switch is enabled, and the digital-to-analog converter is enabled, (iii) a (1_1)-st digital output data converted from the (1_1)-st output voltage outputted from the amplifier is outputted through the analog-to-digital converter by a (1_3)-rd operation mode in which the (1_1)-st specific memory cell is disabled, the (2_1)-st specific memory cell is disabled, the (1_1)-st switch is disabled, the (2_2)-nd switch is disabled, the digital-to-analog converter is disabled, and the analog-to-digital converter is enabled.

As one example, in the (1_1)-st operation mode, the analog-to-digital converter is enabled to convert a (2_1)-st output voltage, outputted from the amplifier, to thereby output a (2_1)-st digital output data, wherein the (2_1)-st output voltage is outputted by amplifying a (2_1)-st analog voltage corresponding to the (2_1)-st digital record data written on the (2_1)-st specific memory cell or on a (2_2)-nd specific memory cell, which is a selected one of other memory cells that are connected to the second specific bitline.

As one example, in the (1_2)-nd operation mode, at least one of the (2_1)-st specific memory cell and the (2_2)-nd specific memory cell is enabled, and the (2_1)-st input analog voltage converted from the (2_1)-st digital output data through the digital-to-analog converter is applied to the second specific bitline to thereby allow said at least one of the (2_1)-st specific memory cell and the (2_2)-nd specific memory cell to be refreshed.

As one example, in an operation mode for reading a (2_1)-st digital record data written on a (2_1)-st specific memory cell among the second specific memory cells connected to the second specific bitline after writing a (1_1)-st digital record data on a (1_1)-st specific memory cell among the first specific memory cells connected to the first specific bitline, (i) the second specific bitline is pre-charged by a (2_1)-st operation mode in which a second specific reference voltage switch connected to the second specific bitline is enabled and the (1_2)-nd switch is enabled, (ii) (ii-1) a (2_1)-st analog voltage corresponding to the (2_1)-st digital record data written on the (2_1)-st specific memory cell is amplified through the amplifier to output a (2_1)-st output voltage, and (ii-2) a (1_1)-st input analog voltage converted from the (1_1)-st digital record data to be written on the (1_1)-st specific memory cell through the digital-to-analog converter is applied to the first specific bitline to write the (1_1)-st digital record data on the (1_1)-st specific memory cell, by a (2_2)-nd operation mode in which the second specific reference voltage switch is disabled, the (1_1)-st specific memory cell is enabled, the (2_1)-nd specific memory cell is enabled, the (2_1)-st switch is enabled, and the digital-to-analog converter is enabled, (iii) a (2_1)-st digital output data converted from the (2_1)-st output voltage outputted from the amplifier is outputted through the analog-to-digital converter by a (2_3)-rd operation mode in which the (1_1)-st specific memory cell is disabled, the (2_1)-st specific memory cell is disabled, the (1_2)-nd switch is disabled, the (2_1)-st switch is disabled, the digital-to-analog converter is disabled, and the analog-to-digital converter is enabled.

As one example, in the (2_1)-st operation mode, the analog-to-digital converter is enabled to convert a (1_1)-st output voltage, outputted from the amplifier, to thereby output a (1_1)-st digital output data, wherein the (1_1)-st output voltage is outputted by amplifying a (1_1)-st analog voltage corresponding to the (1_1)-st digital record data written on the (1_1)-st specific memory cell or on a (1_2)-nd specific memory cell, which is a selected one of other memory cells that are connected to the first specific bitline.

As one example, in the (2_2)-nd operation mode, at least one of the (1_1)-st specific memory cell and the (1_2)-nd specific memory cell is enabled, and the (1_1)-st input analog voltage converted from the (1_1)-st digital output data through digital-to-analog converter is applied to the first specific bitline to thereby allow said at least one of the (1_1)-st specific memory cell and the (1_2)-nd specific memory cell to be refreshed.

As one example, the amplifier includes (i) an operational amplifier in which the first input end is a non-inverting input end and the second input end is an inverting input end, (ii) a feedback capacitor, and (iii) a feedback switch, wherein the feedback capacitor and the feedback switch are connected in between the second input end and the output end, and are formed in parallel with each other.

As one example, the feedback switch is enabled when the first specific reference voltage switch, which is connected to the first specific bitline, is enabled, or the second specific reference voltage switch, which is connected to the second specific bitline, is enabled.

### Effects of the Invention

The present disclosure has an effect of reducing an overall circuit area of a memory device by allowing circuit elements included in the memory device to control two or more bitlines.

The present disclosure has another effect of reducing idle time of the circuit elements included in the memory device.

The present disclosure has still another effect of improving a data processing capability per unit time of the circuit elements included in the memory device.

### BRIEF DESCRIPTION OF THE DRAWINGS

The following drawings to be used to explain example embodiments of the present disclosure are only part of example embodiments of the present disclosure and other drawings can be obtained based on the drawings by those skilled in the art of the present disclosure without inventive work.

FIGS. 1A and 1B are drawings for explaining operations of a conventional DRAM.

FIG. 2 is a drawing schematically illustrating a memory device in accordance with one example embodiment of the present disclosure.

FIG. 3A to FIG. 4C are drawings schematically illustrating timing diagrams for various operation modes of the memory device in accordance with one example embodiment of the present disclosure.

FIG. 5 is a drawing for explaining differences between the conventional memory device and the memory device in accordance with one example embodiment of the present disclosure.

### DETAILED DESCRIPTION OF THE PREFERRED EMBODIMENTS

Detailed explanation on the present disclosure to be made below refer to attached drawings and diagrams illustrated as specific embodiment examples under which the present disclosure may be implemented to make clear of purposes, technical solutions, and advantages of the present disclosure. These embodiments are described in sufficient detail to enable those skilled in the art to practice the disclosure.

Besides, in the detailed description and claims of the present disclosure, a term “include” and its variations are not intended to exclude other technical features, additions, components or steps. Other objects, benefits, and features of the present disclosure will be revealed to one skilled in the art, partially from the specification and partially from the implementation of the present disclosure. The following examples and drawings will be provided as examples but they are not intended to limit the present disclosure.

Moreover, the present disclosure covers all possible combinations of example embodiments indicated in this specification. It is to be understood that the various embodiments of the present disclosure, although different, are not necessarily mutually exclusive. For example, a particular feature, structure, or characteristic described herein in connection with one embodiment may be implemented within other embodiments without departing from the spirit and scope of the present disclosure. In addition, it is to be understood that the position or arrangement of individual elements within each disclosed embodiment may be modified without departing from the spirit and scope of the present disclosure. The following detailed description is, therefore, not to be taken in a limiting sense, and the scope of the present disclosure is defined only by the appended claims, appropriately interpreted, along with the full range of equivalents to which the claims are entitled. In the drawings, like numerals refer to the same or similar functionality throughout the several views.

To allow those skilled in the art to the present disclosure to be carried out easily, the example embodiments of the present disclosure by referring to attached drawings will be explained in detail as shown below. A memory device according to the present invention may be a RAM (i. e., Random Access Memory) such as a DRAM (i.e., Dynamic Random Access Memory), an SDRAM (i.e., Synchronous DRAM), an SRAM (i. e., Static Ram), a DDR SDRAM (i. e., Double Date Rate SDRAM), a DDR2 SDRAM, a DDR3 SDRAM, a PRAM (i.e., Phase change RAM), an MRAM (i.e., Magnetic RAM), a RRAM (i.e., Resistive RAM), etc., and the following description will focus on DRAM. Additionally, a memory cell may include a switching element that is switched by a wordline signal and a cell capacitor that stores charges, but for a convenience of explanation, the cell capacitor may also be referred to as the memory cell.

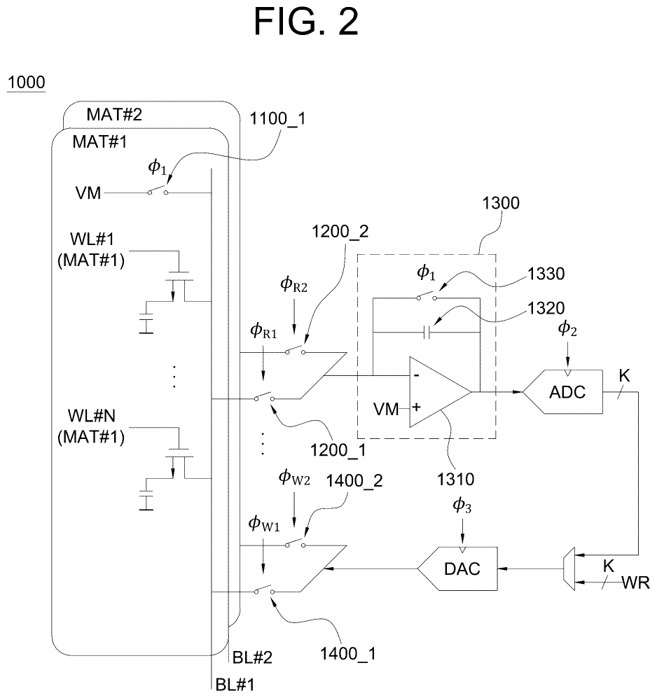

FIG. 2 is a drawing schematically illustrating the memory device in accordance with one example embodiment of the present disclosure.

By referring to FIG. 2, the memory device 1000 in accordance with one example embodiment of the present disclosure may include a first memory cell matrix MAT#1 in which first wordlines and first bitlines are configured as rows and columns, and first memory cells, which are operated by signals of the first wordlines, are connected to the first bitlines in the first memory cell matrix MAT#1.

Further, first reference voltage switches configured to provide a reference voltage VM when being enabled in a pre-charge mode may be connected to each of the first bitlines.

Furthermore, a (1_1)-st switch 1200_1 may have one end connected to a first specific bitline BL#1, which is one of the first bitlines included in the first memory cell matrix MAT#1.

Additionally, the memory device 1000 in accordance with one example embodiment of the present disclosure may include a second memory cell matrix MAT#2 in which second wordlines and second bitlines are configured as rows and columns, and second memory cells, which are operated by signals of the second wordlines, are connected to the second bitlines in the second memory cell matrix MAT#2.

Further, second reference voltage switches configured to provide the reference voltage VM when being enabled in the pre-charge mode may be connected to each of the second bitlines.

Furthermore, a (1_2)-nd switch 1200_2 may have one end connected to a second specific bitline BL#2, which is one of the second bitlines included in the second memory cell matrix MAT#2.

Moreover, an amplifier 1300 configured to amplify an analog voltage written on a selected one of first specific memory cells connected to the first specific bitline or a selected one of second specific memory cells connected to the second specific bitline may have a first input end connected to a reference voltage end that supplies the reference voltage VM and a second input end connected to an opposite end of the (1_1)-st switch 1200_1 and an opposite end of the (1_2)-nd switch 1200_2.

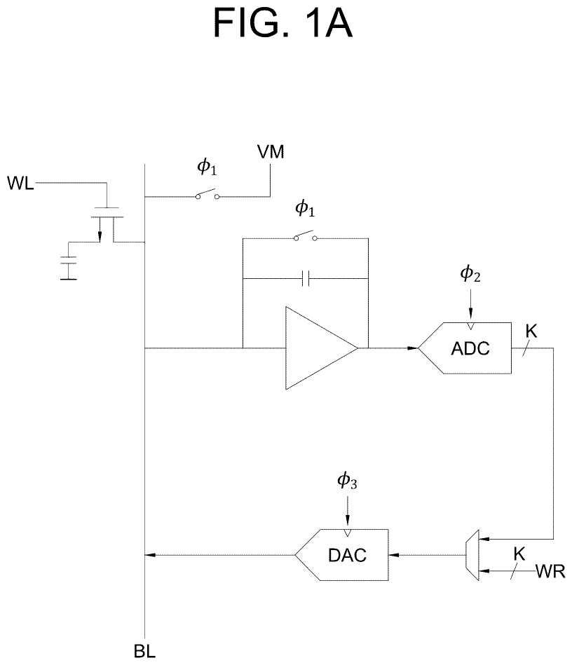

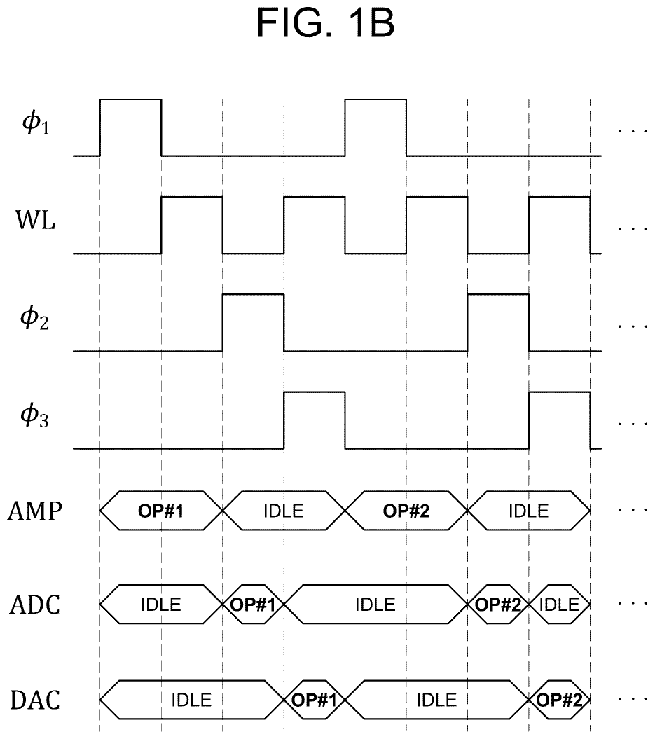

That is, in the conventional memory device illustrated in FIG. 1A, the amplifier and the bitline are directly connected with each other, however, according to the memory device 1000 of the present disclosure illustrated in FIG. 2, the (1_1)-st switch 1200_1 and the (1_2)-nd switch 1200_2 are formed in between the amplifier 1300 and the bitlines (i.e., BL#1 and BL#2), thereby allowing the first specific bitline BL#1 of the first memory cell matrix MAT#1 and the second specific bitline BL#2 of the second memory cell matrix MAT#2 to be distinguished.

Meanwhile, the amplifier 1300 may include (i) an operational amplifier 1310 having the first input end as a non-inverting input end and the second input end as an inverting input end, (ii) a feedback capacitor 1320, and (iii) a feedback switch 1330. Specifically, the feedback capacitor 1320 and the feedback switch 1330 may be connected in between the second input end and an output end of the amplifier 1310, and may be formed in parallel with each other.

Herein, the feedback switch 1330 may be enabled when a first specific reference voltage switch 1100_1, which is connected to the first specific bitline BL#1, is enabled, or a second specific reference voltage switch (i.e., not illustrated), which is connected to the second specific bitline BL#2, is enabled, thereby allowing an amount of charge stored in the feedback capacitor 1320 to be 0.

Further, an analog-to-digital converter ADC configured to convert an output voltage of the amplifier 1300 into a digital output data may be connected to the output end of the amplifier 1300.

Furthermore, the memory device 1000 in accordance with one example embodiment f the present disclosure may include a digital-to-analog converter DAC configured to convert (i) digital record data to be written on one of memory cells connected to the first specific bitline BL#1 or the second specific bitline BL#2 or (ii) the digital output data outputted from the analog-to-digital converter ADC, into an analog voltage, to thereby output analog input data.

Moreover, a (2_1)-st switch 1400_1 may have one end connected to the first specific bitline BL#1 and an opposite end connected to an output end of the digital-to-analog converter DAC.

In addition, a (2_2)-nd switch may have one end connected to the second specific bitline BL#2 and an opposite end connected to the output end of the digital-to-analog converter DAC.

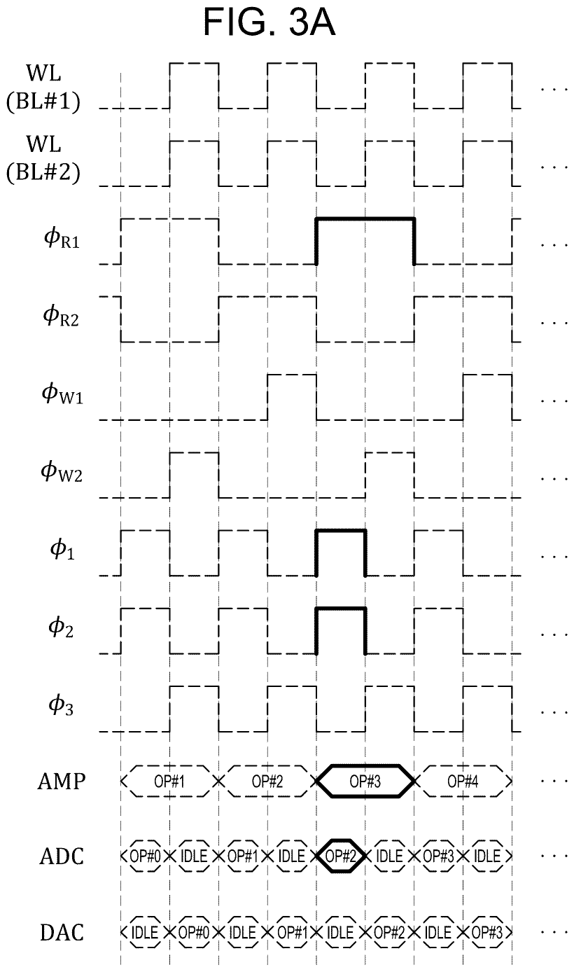

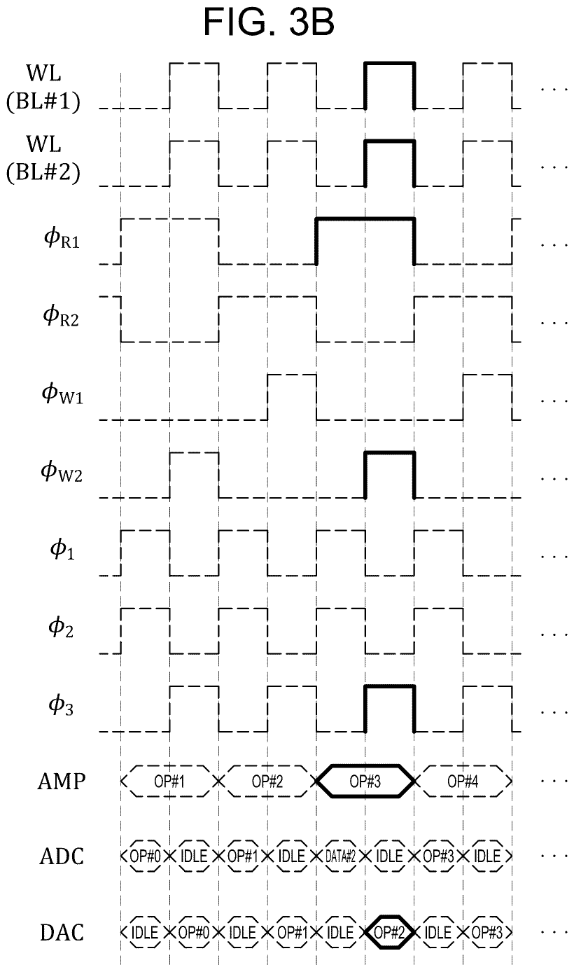

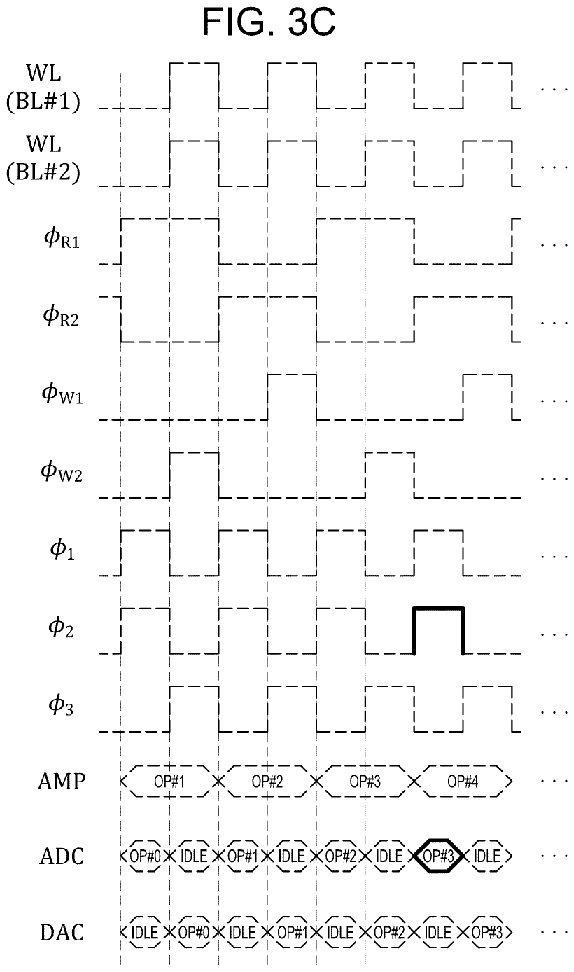

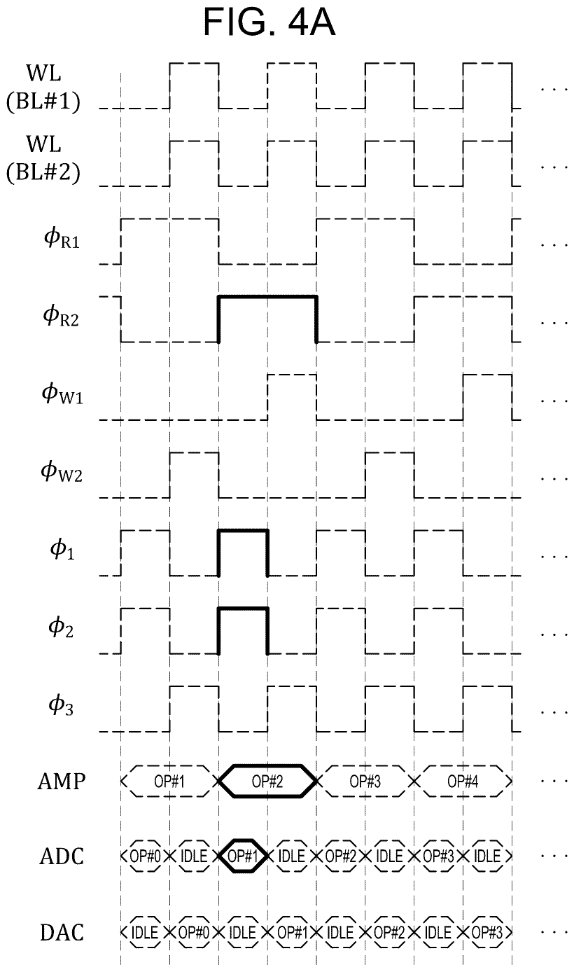

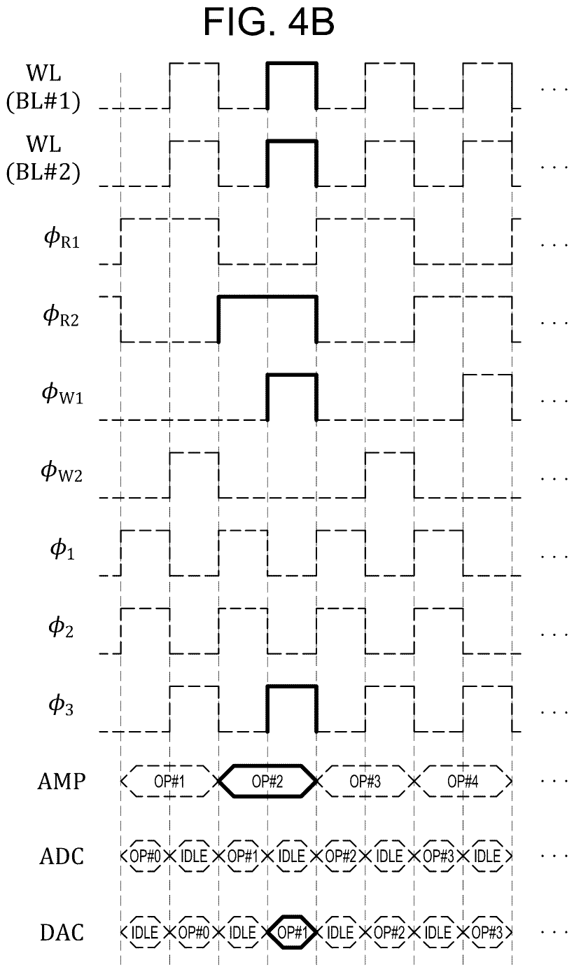

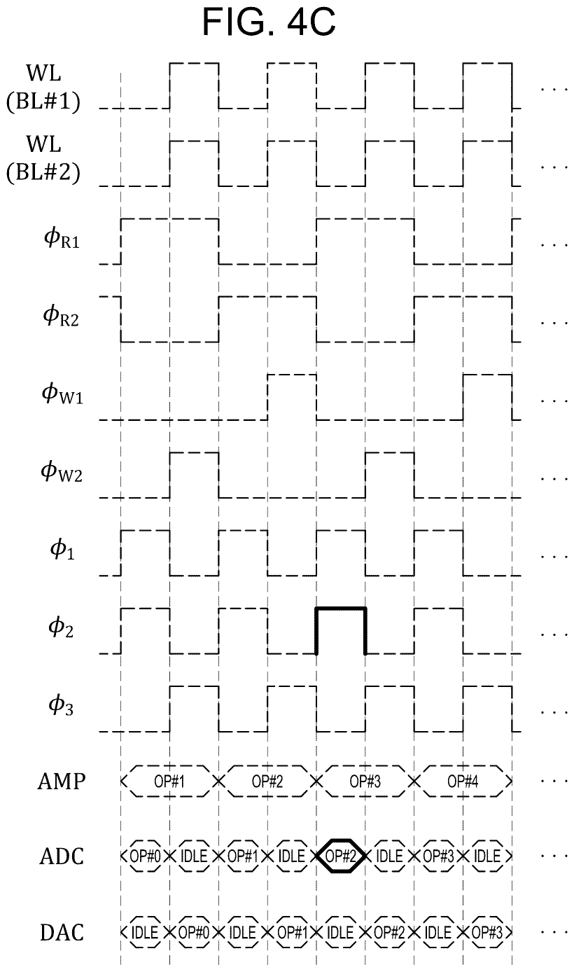

Various operation modes of the memory device 1000 in accordance with one example embodiment of the present disclosure described above are explained with reference to timing diagrams illustrated in FIGS. 3A to 4C.

For reference, in each of FIGS. 3A to 4C, parts of the timing diagrams corresponding to each of operation modes that will be described below are indicated with bold solid lines, and parts of the timing diagram not corresponding to each of operation modes are indicated with dotted lines.

First, referring to FIGS. 3A to 3C, operations modes of writing data on a selected one of memory cells connected to the second specific bitline BL#2 or reading data recorded on a selected one of memory cells connected to of the second specific bitline BL#2, while reading data written on a (1_1)-st specific memory cell of the first specific bitline BL#1 will be explained.

Referring to FIG. 3A, in an operation mode for writing a (2_1)-st digital record data on a (2_1)-st specific memory cell among the second specific memory cells connected to the second specific bitline BL#2 after reading a (1_1)-st digital record data written on a (1_1)-st specific memory cell among the first specific memory cells connected to the first specific bitline BL#1, a (1_1)-st operation mode may enable the first specific reference voltage switch 1100_1 connected to the first specific bitline BL#1 and enable the (1_1)-st switch 1200_1.

Accordingly, the first specific bitline BL#1 may be pre-charged when the reference voltage VM is supplied to the first specific bitline BL#1. That is, a charge according to the reference voltage VM may be charged in a parasitic capacitor generated in the first specific bitline BL#1.

Further, referring to FIG. 3B, according to a (1_2)-nd operation mode, the first specific reference voltage switch 1100_1 may be disabled, the (1_1)-st specific memory cell may be enabled according to a first specific wordline signal WL (BL#1), the (2_1)-st specific memory cell may be enabled according to a second specific wordline signal WL (BL#2), the (2_2)-nd switch 1400_2 may be enabled, and the digital-to-analog converter DAC may be enabled.

Accordingly, the amplifier AMP may output a (1_1)-st output voltage by amplifying a (1_1)-st analog voltage corresponding to the (1_1)-st digital record data written on the (1_1)-st specific memory cell. Herein, if the amplifier AMP is a switched capacitor operational amplifier using the feedback capacitor 1320, the (1_1)-st output voltage acquired by amplifying the (1_1)-st analog voltage corresponding to the (1_1)-st digital record data written on the (1_1)-st specific memory cell through the capacitive feedback of the feedback capacitor 1320 may be outputted.

In addition, the (2_1)-st digital record data to be written on the (2_1)-st specific memory cell is converted to a (2_1)-st input analog voltage through the digital-to-analog converter DAC, that is, an input analog voltage (i.e., the (2_1)-st input analog voltage) corresponding to a bit code of a digital data (i.e., the (2_1)-st digital record data) may be outputted by the digital-to-analog converter DAC. And the (2_1)-st input analog voltage may be applied to the second specific bitline BL#2, to thereby write the (2_1)-st digital record data on the (2_1)-st specific memory cell.

Further, referring to FIG. 3C, in a (1_3)-rd operation mode, the (1_1)-st specific memory cell may be disabled, the (2_1)-st specific memory cell may be disabled, the (1_1)-st switch 1200_1 may be disabled, the (2_2)-nd switch 1400_2 may be disabled, the digital-to-analog converter may be disabled, and the analog-to-digital converter may be enabled.

Accordingly, the analog-to-digital converter ADC may output a (1_1)-st digital output data by converting the (1_1)-st output voltage outputted from the amplifier AMP. That is, the analog-to-digital converter ADC may output a bit code corresponding to the (1_1)-st output voltage of the amplifier AMP. Herein, the memory device 1000 in accordance with one example embodiment of the present disclosure may be a multi-level memory device for recording multi-bit data, and details of reading and writing digital data in the multi-level memory device may be easily understood by referring to Korean Registered Patent No. 10-2416605 and Korean Registered Patent No. 10-2361253 owned by the applicant of the present invention.

Meanwhile, referring to FIG. 3A, in the (1_1)-st operation mode, the analog-to-digital converter ADC may be enabled.

Accordingly, the analog-to-digital converter ADC may output a (2_1)-st digital output data by converting a (2_1)-st output voltage outputted from the amplifier. That is, the analog-to-digital converter ADC may output a bit code corresponding to the (2_1)-st output voltage of the amplifier AMP.

For reference, the (2_1)-st output voltage may be an amplified voltage of a (2_1)-st analog voltage corresponding to the (2_1)-st digital record data written on the (2_1)-st specific memory cell or on a (2_2)-nd specific memory cell, which is a selected one of other memory cells that are connected to the second specific bitline BL#2. Herein, the (2_1)-st analog voltage is amplified by the capacitive feedback in the amplifier AMP.

That is, in addition to performing an operation of pre-charging the first specific bitline BL#1 to read data recorded on the (1_1)-st specific memory cell connected to the first specific bitline BL#1, an operation of the analog-to-digital converter ADC for reading data recorded on the (2_1)-st specific memory cell or on the (2_2)-nd specific memory cell, which is the selected one of other memory cells that are connected to the second specific bitline BL#2 may be performed.

Further, referring to FIG. 3B, in the (1_2)-nd operation mode, unlike inputting the (2_1)-st digital record data to be written on the (2_1)-st specific memory cell to the digital-to-analog converter DAC, the (2_1)-st digital output data, which is an output signal of the analog-to-digital converter ADC that has read a digital data written on at least one of the (2_1)-st specific memory cell and the (2_2)-nd specific memory cell during a previous operation, is inputted to the digital-to-analog converter DAC, and therefore, the digital-to-analog converter DAC may convert the (2_1)-st digital output data to the (2_1)-st input analog voltage, that is, an analog voltage (i.e., the (2_1)-st input analog voltage) corresponding to a bit code of a digital data (i.e., the (2_1)-st digital output data) is outputted by the digital-to-analog converter, and the (2_1)-st input analog voltage is applied to the second specific bitline BL#2 to thereby allow said at least one (i.e., a memory cell that had recorded the (2_1)-st digital record data) between the (2_1)-st specific memory cell and the (2_2)-nd specific memory cell to be refreshed.

That is, along with an operation of reading the (1_1)-st digital record data recorded in the (1_1)-st specific memory cell, a refresh operation necessary for a process of reading data (i.e., the (2_1)-st record digital data) recorded in one of the (2_1)-st specific memory cell and the (2_2)-nd specific memory cell may be performed.

Above, by referring to FIGS. 3A to 3C, the operations modes of writing data on a selected one of memory cells connected to the second specific bitline BL #2 or reading data recorded on a selected one of memory cells connected to the second specific bitline BL #2, while reading data written on the (1_1)-st specific memory cell of the first specific bitline BL#1 was explained.

Below, by referring to FIGS. 4A to 4C, operations modes of writing data on a selected one of memory cells connected to the first specific bitline BL#1 or reading data recorded on a selected one of memory cells connected to the first specific bitline BL#1, while reading data written on a (2_1)-st specific memory cell of the second specific bitline BL#2 will be explained.

Referring to FIG. 4A, in an operation mode for reading a (2_1)-st digital record data written on the (2_1)-st specific memory cell among the second specific memory cells connected to the second specific bitline after writing the (1_1)-st digital record data on the (1_1)-st specific memory cell among the first specific memory cells connected to the first specific bitline BL#1, a (2_1)-st operation mode may enable the second specific reference voltage switch connected to the second specific bitline BL#2 and enable the (1_2)-nd switch 1200_2.

Accordingly, the second specific bitline BL#2 may be pre-charged when the reference voltage VM is supplied to the second specific bitline BL#2. That is, a charge according to the reference voltage VM may be charged in a parasitic capacitor generated in the second specific bitline BL #2.

Further, referring to FIG. 4B, according to a (2_2)-nd operation mode, the second specific reference voltage switch may be disabled, the (1_1)-st specific memory cell may be enabled according to the first specific wordline signal WL (BL#1), the (2_1)-st specific memory cell may be enabled according to the second specific wordline signal WL(BL#2), the (2_1)-st switch 1400_1 may be enabled, and the digital-to-analog converter DAC may be enabled.

Accordingly, the amplifier AMP may output the (2_1)-st output voltage by amplifying the (2_1)-st analog voltage corresponding to the (2_1)-st digital record data written on the (2_1)-st specific memory cell. Herein, if the amplifier AMP is the switched capacitor operational amplifier using the feedback capacitor 1320, the (2_1)-st output voltage acquired by amplifying the (2_1)-st analog voltage corresponding to the (2_1)-st digital record data written on the (2_1)-st specific memory cell through the capacitive feedback of the feedback capacitor 1320 may be outputted.

In addition, the (1_1)-st digital record data to be written on to be written on the (1_1)-st specific memory cell is converted to a (1_1)-st input analog voltage through the digital-to-analog converter DAC, that is, an input analog voltage (i.e., the (1_1)-st input analog voltage) corresponding to a bit code of a digital data (i.e., the (1_1)-st digital record data) may be outputted by the digital-to-analog converter DAC. And the (1_1)-st input analog voltage may be applied to the first specific bitline BL#1, to thereby allow the (1_1)-st digital record data to be written on the (1_1)-st specific memory cell.

Further, referring to FIG. 4C, in a (2_3)-rd operation mode, the (1_1)-st specific memory cell may be disabled, the (2_1)-st specific memory cell may be disabled, the (1_2)-nd switch 1200_2 may be disabled, the (2_1)-st switch 1400_1 may be disabled, the digital-to-analog converter may be disabled, and the analog-to-digital converter may be enabled.

Accordingly, the analog-to-digital converter ADC may output a (2_1)-st digital output data by converting the (2_1)-st output voltage outputted from the amplifier AMP. That is, the analog-to-digital converter ADC may output a bit code corresponding to the (2_1)-st output voltage of the amplifier AMP.

Meanwhile, referring to FIG. 4A, in the (2_1)-st operation mode, the analog-to-digital converter ADC may be enabled.

Accordingly, the analog-to-digital converter ADC may output the (1_1)-st digital output data by converting a (1_1)-st output voltage outputted from the amplifier AMP. That is, the analog-to-digital converter ADC may output a bit code corresponding to the (1_1)-st output voltage of the amplifier AMP.

For reference, the (1_1)-st output voltage may be an amplified voltage of the (1_1)-st analog voltage corresponding to the (1_1)-st digital record data written on the (1_1)-st specific memory cell or on a (1_2)-nd specific memory cell, which is a selected one of other memory cells that are connected to the first specific bitline BL#1. Herein, the (1_1)-st analog voltage is amplified by the capacitive feedback in the amplifier AMP.

That is, in addition to performing an operation of pre-charging the second specific bitline BL#2 to read data recorded on the (2_1)-st specific memory cell connected to the second specific bitline BL#2, an operation of the analog-to-digital converter ADC for reading data recorded on the (1_1)-st specific memory cell or on the (1_2)-nd specific memory cell, which is the selected one of other memory cells that are connected to the first specific bitline BL#1 may be performed.

Further, referring to FIG. 4B, in the (2_2)-nd operation mode, unlike inputting the (1_1)-st digital record data to be written on the (1_1)-st specific memory cell to the digital-to-analog converter DAC, the (1_1)-st digital output data, which is an output signal of the analog-to-digital converter ADC that has read a digital data written on at least one of the (1_1)-st specific memory cell and the (1_2)-nd specific memory cell during a previous operation, is inputted to the digital-to-analog converter DAC and therefore, the digital-to-analog converter DAC may convert the (1_1)-st digital output data to the (1_1)-st input analog voltage, that is, an analog voltage (i.e., the (1_1)-st input analog voltage) corresponding to a bit code of a digital data (i.e., the (1_1)-st digital output data) is outputted by the digital-to-analog converter, and the (1_1)-st input analog voltage is applied to the first specific bitline BL#1 to thereby allow said at least one (i.e., a memory cell that had recorded the (1_1)-st digital record data) between the (1_1)-st specific memory cell and the (1_2)-nd specific memory cell to be refreshed.

That is, along with an operation of reading the (2_1)-st digital record data recorded in the (2_1)-st specific memory cell, a refresh operation necessary for a process of reading data i.e., the (1_1)-st digital record data) recorded in one of the (1_1)-st specific memory cell and the (1_2)-nd specific memory cell may be performed.

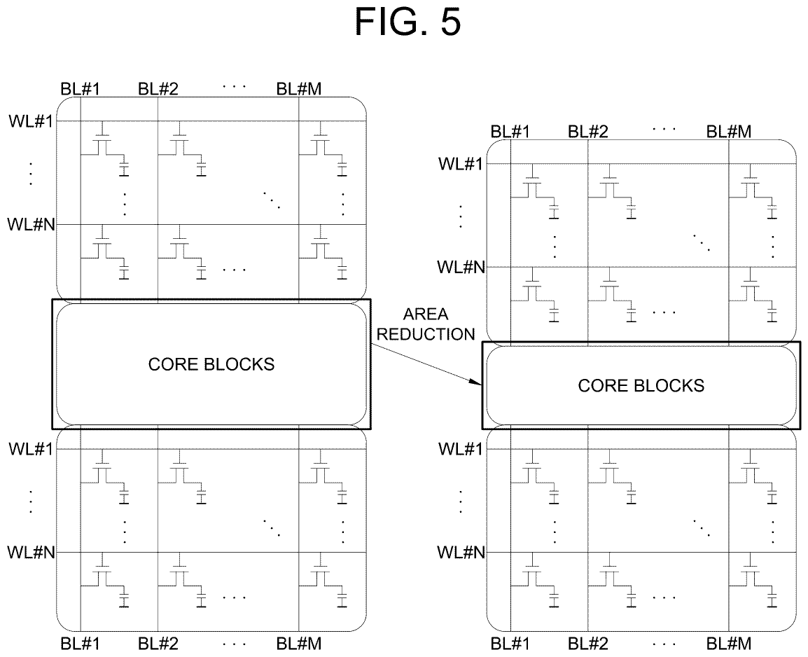

Meanwhile, FIG. 5 is a drawing schematically illustrating a conventional memory device on the left side and the memory device 1000 on the right side in accordance with one example embodiment of the present disclosure.

As previously explained, according to the conventional memory device, the amplifier, the analog-to-digital converter, and the digital-to-analog converter had to be added for each of bitlines of a memory cell matrix.

Therefore, when there are two memory cell matrices with M bitlines, 2M amplifiers, 2M analog-to-digital converters, and 2M digital-to-analog converters were required in the past.

On the other hand, according to the memory device 1000 of the present disclosure, even in case of two memory cell matrices each having M bit lines, it only requires M amplifiers, M analog-to-digital converters, and M digital-to-analog converters.

Through this, a total circuit area of the memory device 1000 in accordance with one example embodiment of the present disclosure may be reduced when compared to a total circuit area of the conventional memory device. Therefore, a manufacturing cost of the memory device 1000 may be drastically reduced.

As seen above, the present disclosure has been explained by specific matters such as detailed components, limited embodiments, and drawings. They have been provided only to help more general understanding of the present disclosure. It, however, will be understood by those skilled in the art that various changes and modification may be made from the description without departing from the spirit and scope of the disclosure as defined in the following claims.

Accordingly, the thought of the present disclosure must not be confined to the explained embodiments, and the following patent claims as well as everything including variations equal or equivalent to the patent claims pertain to the category of the thought of the present disclosure.

What is claimed is:

1. A memory device including memory cells operated by wordlines and bitlines to store data therein, comprising:
a (1_1)-st switch having one end connected to a first specific bitline which is one of bitlines included in a first memory cell matrix, wherein first wordlines and first bitlines are configured as rows and columns in the first memory cell matrix, wherein first memory cells operated by signals of the first wordlines are connected to the first bitlines in the first memory cell matrix, wherein first reference voltage switches configured to provide a reference voltage when being enabled in a pre-charge mode are connected to the first bitlines in the first memory cell matrix;
a (1_2)-nd switch having one end connected to a second specific bitline which is one of bitlines included in a second memory cell matrix, wherein second wordlines and second bitlines are configured as rows and columns in the second memory cell matrix, wherein second memory cells operated by signals of the second wordlines are connected to the second bitlines in the second memory cell matrix, wherein second reference voltage switches configured to provide the reference voltage when being enabled in the pre-charge mode are connected to the second bitlines in the second memory cell matrix;
an amplifier configured to amplify an analog voltage written on a selected one of first specific memory cells connected to the first specific bitline or a selected one of second specific memory cells connected to the second specific bitline, wherein the amplifier has a first input end connected to a reference voltage end that supplies the reference voltage and a second input end connected to an opposite end of the (1_1)-st switch and an opposite end of the (1_2)-nd switch;
an analog-to-digital converter connected to an output end of the amplifier, wherein the analog-to-digital converter is configured to convert an output voltage of the amplifier into digital data and thus generate digital output data;
a digital-to-analog converter configured to convert (i) digital record data to be written on one of memory cells connected to the first specific bitline or the second specific bitline or (ii) the digital output data outputted from the analog-to-digital converter, into an analog voltage, to thereby output analog input data;
a (2_1)-st switch having one end connected to the first specific bitline and an opposite end connected to an output end of the digital-to-analog converter; and
a (2_2)-nd switch having one end connected to the second specific bitline and an opposite end connected to an output end of the digital-to-analog converter.

2. The memory device of claim 1, wherein, in an operation mode for writing a (2_1)-st digital record data on a (2_1)-st specific memory cell among the second specific memory cells connected to the second specific bitline after reading a (1_1)-st digital record data written on a (1_1)-st specific memory cell among the first specific memory cells connected to the first specific bitline, (i) the first specific bitline is pre-charged by a (1_1)-st operation mode in which a first specific reference voltage switch connected to the first specific bitline is enabled and the (1_1)-st switch is enabled, (ii) (ii-1) a (1_1)-st analog voltage corresponding to the (1_1)-st digital record data written on the (1_1)-st specific memory cell is amplified through the amplifier to output a (1_1)-st output voltage, and (ii-2) a (2_1)-st input analog voltage converted from the (2_1)-st digital record data to be written on the (2_1)-st specific memory cell through the digital-to-analog converter is applied to the second specific bitline to write the (2_1)-st digital record data on the (2_1)-st specific memory cell, by a (1_2)-nd operation mode in which the first specific reference voltage switch is disabled, the (1_1)-st specific memory cell is enabled, the (2_1)-st specific memory cell is enabled, the (2_2)-nd switch is enabled, and the digital-to-analog converter is enabled, (iii) a (1_1)-st digital output data converted from the (1_1)-st output voltage outputted from the amplifier is outputted through the analog-to-digital converter by a (1_3)-rd operation mode in which the (1_1)-st specific memory cell is disabled, the (2_1)-st specific memory cell is disabled, the (1_1)-st switch is disabled, the (2_2)-nd switch is disabled, the digital-to-analog converter is disabled, and the analog-to-digital converter is enabled.

3. The memory device of claim 2, wherein, in the (1_1)-st operation mode, the analog-to-digital converter is enabled to convert a (2_1)-st output voltage, outputted from the amplifier, to thereby output a (2_1)-st digital output data, wherein the (2_1)-st output voltage is outputted by amplifying a (2_1)-st analog voltage corresponding to the (2_1)-st digital record data written on the (2_1)-st specific memory cell or on a (2_2)-nd specific memory cell, which is a selected one of other memory cells that are connected to the second specific bitline.

4. The memory device of claim 3, wherein, in the (1_2)-nd operation mode, at least one of the (2_1)-st specific memory cell and the (2_2)-nd specific memory cell is enabled, and the (2_1)-st input analog voltage converted from the (2_1)-st digital output data through the digital-to-analog converter is applied to the second specific bitline to thereby allow said at least one of the (2_1)-st specific memory cell and the (2_2)-nd specific memory cell to be refreshed.

5. The memory device of claim 1, wherein, in an operation mode for reading a (2_1)-st digital record data written on a (2_1)-st specific memory cell among the second specific memory cells connected to the second specific bitline after writing a (1_1)-st digital record data on a (1_1)-st specific memory cell among the first specific memory cells connected to the first specific bitline, (i) the second specific bitline is pre-charged by a (2_1)-st operation mode in which a second specific reference voltage switch connected to the second specific bitline is enabled and the (1_2)-nd switch is enabled, (ii) (ii-1) a (2_1)-st analog voltage corresponding to the (2_1)-st digital record data written on the (2_1)-st specific memory cell is amplified through the amplifier to output a (2_1)-st output voltage, and (ii-2) a (1_1)-st input analog voltage converted from the (1_1)-st digital record data to be written on the (1_1)-st specific memory cell through the digital-to-analog converter is applied to the first specific bitline to write the (1_1)-st digital record data on the (1_1)-st specific memory cell, by a (2_2)-nd operation mode in which the second specific reference voltage switch is disabled, the (1_1)-st specific memory cell is enabled, the (2_1)-nd specific memory cell is enabled, the (2_1)-st switch is enabled, and the digital-to-analog converter is enabled, (iii) a (2_1)-st digital output data converted from the (2_1)-st output voltage outputted from the amplifier is outputted through the analog-to-digital converter by a (2_3)-rd operation mode in which the (1_1)-st specific memory cell is disabled, the (2_1)-st specific memory cell is disabled, the (1_2)-nd switch is disabled, the (2_1)-st switch is disabled, the digital-to-analog converter is disabled, and the analog-to-digital converter is enabled.

6. The memory device of claim 5, wherein, in the (2_1)-st operation mode, the analog-to-digital converter is enabled to convert a (1_1)-st output voltage, outputted from the amplifier, to thereby output a (1_1)-st digital output data, wherein the (1_1)-st output voltage is outputted by amplifying a (1_1)-st analog voltage corresponding to the (1_1)-st digital record data written on the (1_1)-st specific memory cell or on a (1_2)-nd specific memory cell, which is a selected one of other memory cells that are connected to the first specific bitline.

7. The memory device of claim 6, wherein, in the (2_2)-nd operation mode, at least one of the (1_1)-st specific memory cell and the (1_2)-nd specific memory cell is enabled, and the (1_1)-st input analog voltage converted from the (1_1)-st digital output data through digital-to-analog converter is applied to the first specific bitline to thereby allow said at least one of the (1_1)-st specific memory cell and the (1_2)-nd specific memory cell to be refreshed.

8. The memory device of claim 1, wherein the amplifier includes (i) an operational amplifier in which the first input end is a non-inverting input end and the second input end is an inverting input end, (ii) a feedback capacitor, and (iii) a feedback switch, wherein the feedback capacitor and the feedback switch are connected in between the second input end and the output end, and are formed in parallel with each other.

9. The memory device of claim 8, wherein the feedback switch is enabled when the first specific reference voltage switch, which is connected to the first specific bitline, is enabled, or the second specific reference voltage switch, which is connected to the second specific bitline, is enabled.
